(19) United States
(12) Patent Application Publication
(10) Pub. No.: US 2016/0149024 A1
(43) Pub. Date: May 26, 2016

(54) HIGH-ELECTRON MOBILITY TRANSISTOR AND PROCESS TO FORM THE SAME

(71) Applicant: SUMITOMO ELECTRIC INDUSTRIES, LTD., Osaka (JP)

(72) Inventor: Isao MAKABE, Yokohama-shi (JP)

(73) Assignee: SUMITOMO ELECTRIC INDUSTRIES, LTD., Osaka (JP)

(21) Appl. No.: 14/946,087

(22) Filed: Nov. 19, 2015

(30) Foreign Application Priority Data
Nov. 21, 2014 (JP) 2014-236694

(51) Int. Cl. H01L 29/778; H01L 21/02; H01L 29/66; H01L 29/20

(52) U.S. Cl. CPC H01L 29/7787; H01L 29/2003; H01L 21/0254; H01L 21/0262; H01L 29/66462

(57) ABSTRACT

An electron device formed by primarily nitrides semiconductor materials and a method to form the electron device are disclosed. The electron device includes, on the SiC substrate, a buffer layer of AlN, a channel layer of GaN, and an electron supplying layer of AlGaN. The AlGaN layer has the oxygen concentration higher than the carbon concentration in the whole thereof. The AlGaN layer is grown on the channel layer under conditions of: a ratio of the flow rate of the ammonia gas against the flow rate of the gases for Al and Ga is 5000 to 20000; and/or the growth, rate of the AlGaN layer is slower than 0.2 nm/sec.

### BACKGROUND

1. Field of the Invention

The present application relates to an electron device widely called as a high-electron mobility transistor (HEMT) and a process to form the HEMT.

2. Background Arts

A HEMT primarily made of gallium nitride (GaN) and semiconductor materials involved in GaN group has been practically used as a high-power device in applications requesting high power and high breakdown voltage. When a high drain bias is applied to a HEMT having a channel layer made of GaN and materials in the GaN group, such HEMT shows a phenomenon to reduce the drain current thereof even when the gate bias is unchanged, which is conventionally called as the current collapsing. One technique is known in the field to suppress the current collapsing, where the HEMT provides an insulating layer on the surface of the cap layer made of GaN between the gate electrode and the drain electrode. However, the current collapsing caused primarily by the electron supplying layer grown on the channel layer has been out of consideration. The electron supplying layer possibly controls or reduces the current collapsing.

### SUMMARY OF THE INVENTION

One aspect of the present application relates to a semiconductor device, in particular, a nitride semiconductor device that includes a channel layer, an electron supplying layer, and electrodes of the gate, drain, and source. The channel layer includes the first nitride semiconductor. The electron supplying layer includes the second nitride semiconductor containing aluminum (Al). A feature of the electron device according to the present aspect is that the second nitride semiconductor has the oxygen concentration greater than the carbon concentration, where both of the oxygen and the carbon are inevitably imported within the second nitride semiconductor during the growth thereof.

Another aspect of the present application relates to a process to form the nitride semiconductor device. The process comprises (1) growing a first nitride semiconductor layer on the semiconductor substrate; and (2) growing a second nitride semiconductor layer on the first nitride semiconductor layer, where the second nitride semiconductor layer contains aluminum as the group III material and nitrogen as the group V material. A feature of the process of the present application is that the growth of the second semiconductor layer is carried out under the condition that the ratio of the flow rate of the gas source for the group V material to the flow rate of the gas source for the group III material is set greater than 5000 but smaller than 20000, or carried out under the condition of the growth rate of the second nitride semiconductor layer is set slower than 0.2 nm/sec.

### BRIEF DESCRIPTION OF THE DRAWINGS

The foregoing and other purposes, aspects and advantages will be better understood from the following detailed description of a preferred embodiment of the invention with reference to the drawings, in which:

FIG. 1 shows a cross section of a semiconductor device according to an embodiment of the present invention;

FIGS. 2A to 2C show cross sections of the semiconductor device at respective processes;

FIGS. 3A and 3B show cross sections of the semiconductor device at respective processes subsequent to the process shown in FIG. 2C;

FIGS. 4A to 4C show cross sections of the semiconductor device at respective processes subsequent to the process shown in FIG. 3B;

FIG. 5 shows a cross section of a semiconductor device modified from that shown in FIG. 1;

FIG. 6A shows the depth profile of oxygen, carbon and aluminum in the specimen prepared by the process of the present invention, and FIG. 6B shows the depth profile of oxygen, carbon, and aluminum in the other specimen prepared by the process comparable to the present invention;

FIG. 7A compares the drain current vs. drain bias before and after the stress measured for the specimen prepared by the process of the present invention, and FIG. 7B compares the drain current vs. drain bias before and after the stress for the specimen comparable to the present invention;

FIG. 8 shows the oxygen concentration and the carbon concentration in the AlGaN layer against the ratio of the flow rate of the source gases for the group V material against that for the group III material, and

FIG. 9 shows the oxygen concentration and the carbon concentration against the growth rate of the AlGaN layer.

### DETAILED DESCRIPTION

Next, some preferred embodiments according to the present invention will be described as referring to drawings. In the description of the drawings, numerals or symbols same with or similar to each other will refer to elements same with or similar to each other without duplicating explanations.

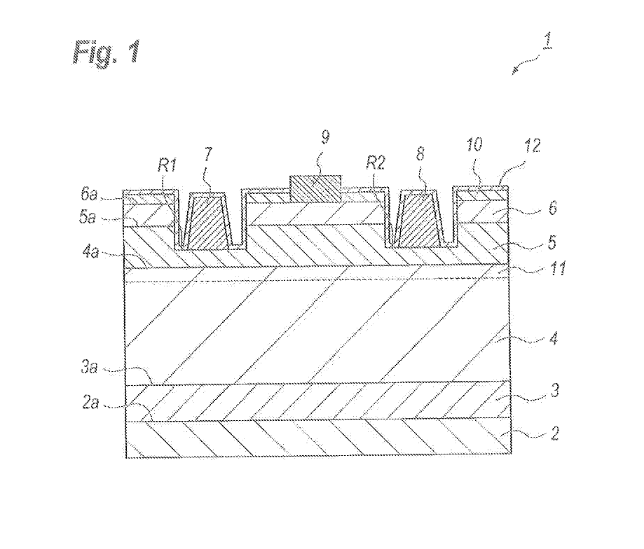

FIG. 1 shows a cross section of a semiconductor device according to an embodiment of the present invention. The semiconductor device, specifically a transistor 1, includes a substrate 2, a buffer layer 3, a channel layer 4, an electron supplying layer 5, a cap layer 6, electrodes, 7 to 9, of the source, drain and the gate, respectively, and a passivation layer 10.

The substrate 2, which is prepared for the epitaxial growth of semiconductor layers, may be made of silicon (Si), silicon carbide (SiC), and/or sapphire (Al₂O₃). The present embodiment uses the substrate made of SiC. The buffer layer 3, which is grown on a surface 2a of the substrate 2 by a thickness of 30 to 200 nm, may be made of aluminum, nitride (AlN). The top surface 2a of the substrate 2 is unnecessary to be a lattice surface, that is the top surface 2a is unnecessary to have a grade requested in other semiconductor devices such as transistors made of GaAs based material and/or integrated circuits (IC) made of Si.

The channel layer 4, which may be made of gallium nitride (GaN) based material and will be called as the first nitride semiconductor layer, is epitaxially grown on a top surface 3a of the buffer layer 3 by a thickness of, for instance, 300 to 1400 nm. Typically, the channel layer 4 is made of GaN. The channel layer 4 may induce a two-dimensional electron gas (2-DEG) in a boundary against the electron supplying layer 5, which may be a channel 11 of the transistor 1.

The electron supplying layer 5 may be made of also GaN based material containing aluminum (Al) and will be called as the second nitride semiconductor layer. The present embodiment provides the electron supplying layer 5 made aluminum-gallium nitride (AlGaN) with a thickness of 10 to 30 nm and. an aluminum composition of 10 to 30%. The electron supplying layer 5 may be an AlInGaN. The Al atoms are preferably distributed within a whole of the electron supplying layer 5 homogeneously and uniformly. The electron supplying layer 5 has maximum concentrations of 1×10¹⁸/cm³ at most for oxygen and carbon, respectively, which is measured by the Secondary Ion Mass Spectroscopy (SIMS), while, the minimum concentrations of oxygen and carbon in the electron supplying layer 5 may be less than the lower limit detectable by the SIMS. In the present embodiment, the concentrations of oxygen and carbon in the electron supplying layer 5 mean respective average concentrations, and the average concentrations of oxygen and carbon may be less than 1×10¹⁸/cm³. Also, the average oxygen concentration in the electron supplying layer 5 is greater than the average carbon concentration in the electron supplying layer 5. Preferably, the oxygen concentration is greater than the carbon concentration in the whole of the electron supplying layer 5.

The cap layer 6, which is grown on the surface 5 a of the electron supplying layer 5, may have a thickness to 1 to 10 nm and made of GaN, preferably n-type GaN.

The source electrode 7 and the drain electrode 8 are provided within recesses, R1 and R2, respectively. The recesses, R1 and R2, are formed by removing portions of the cap layer 6 and the electron supplying layer 5. Two electrodes, 7 and 8, which may make ohmic contacts to the electron supplying layer 5, may be made of stack of titanium (Ti) and aluminum (Al), where titanium (Ti) is in contact to the electron supplying layer 5. Two electrodes, 7 and 8, may further provide other titanium (Ti) on aluminum (Al), that is, a metal stack of Ti, Al, and Ti (Ti/Al/Ti) may be applicable to the source and drain electrodes, 7 and 8.

The gate electrode 9 is provided between the source and drain electrodes, 7 and 8, and on the cap layer 6. The gate electrode 9 may be made of stack of nickel (Ni) and gold (Au), where nickel (Ni) is in contact to the cap layer 6. The gate electrode 9 may be formed on the surface 5 a of the electron supplying layer 5.

The passivation layer 10 covers the surface 6a of the cap layer 6 and protects the cap layer 6. The passivation layer 10 may be made of silicon nitride (SIN).

An insulating film 12 covers the passivation layer 10, and the source and drain electrodes, 7 and 8, the portion of the electron supplying layer 5 and the portion of the cap layer 6 where they are exposed in the recesses, R1 and R2. The insulating film 12 may be also made of silicon nitride (SIN).

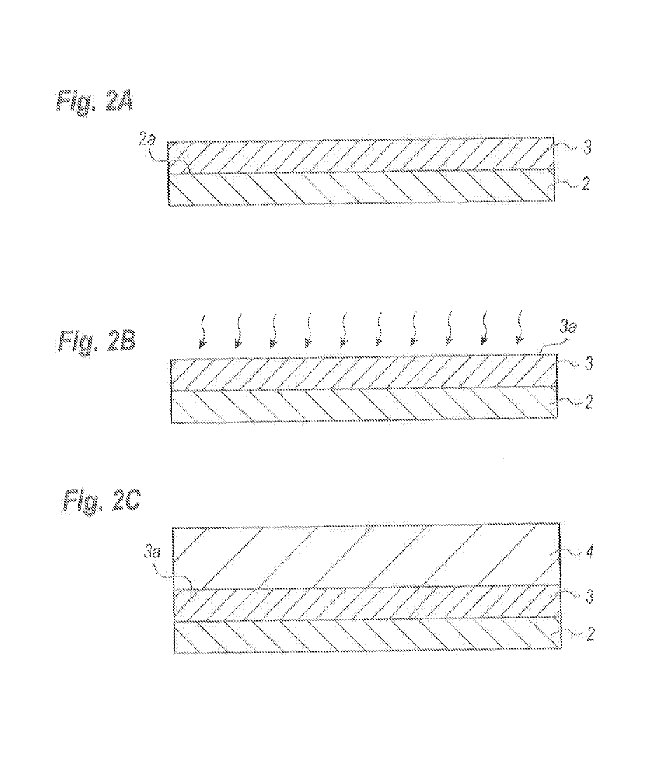

Next, the process to form the semiconductor device will be described as referring to FIGS. 2A to 4C, where these figures show cross section of the semiconductor device during the process.

First, as shown in 2 , the process grows the buffer layer 3 on the substrate 2 made of SiC, which has a semi-insulating characteristic, by the organo-metallic vapor phase epitaxy (OMVPE) which is well-known in the semiconductor engineering. As supplying Al source and N source under the conditions of a growth temperature between 1000 to 1150° C. and growth pressure of 13.7 kPa, the buffer layer 3 of AlN is grown on the substrate 2 by a thickness of 50 nm. The Al source is tri-methyl-aluminum (TMA), while, the N source is ammonia (NH₃) in the present embodiment with a flow rate of 0.5 mol/min.

Next, the second step of the process performs a thermal treatment of the buffer layer 3 at a temperature higher than the growth temperature of the buffer layer 3 as shown, in FIG. 2B, which may sublimate contaminations left on the surface 3a of the buffer layer 3.

Then, the third step of the process grows the channel, layer 4 of GaN on the surface 3a of the buffer layer 3 as supplying Ga source and N source by the OMVPE technique as shown in FIG. 2C. As supplying tri-methyl-gallium (TMG) with a flow rate of 120 μmol/min and ammonia (NH₃) with a flow rate of 0.5 mol/min for the Ga source and the N source, respectively, under the conditions of the growth temperature of 1000 to 1100° C. and the growth pressure of 13.6 kPa, the channel layer 4 of GaN is grown on the AlN buffer layer 3 by a thickness of 1000 nm.

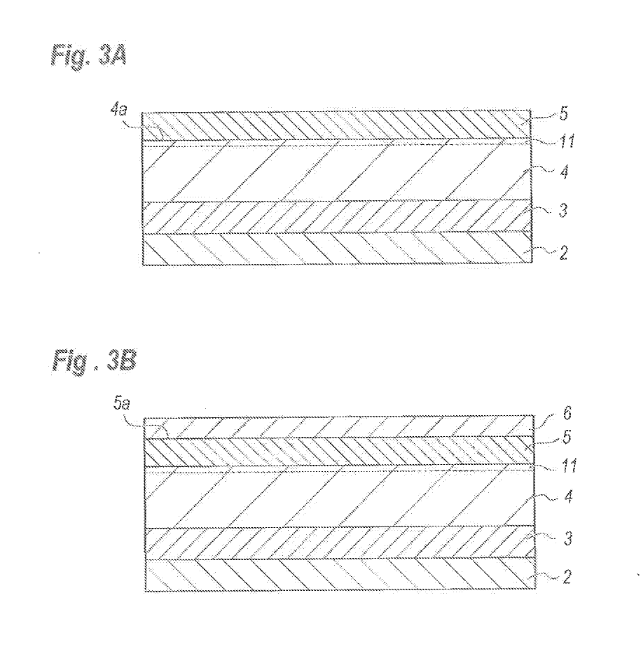

Next, the fourth, step grows the electron supplying layer 5 of AlGaN on the surface 4a of the channel layer 4, as shown in FIG. 3A. As supplying Al source, N source and Ga source under conditions of the growth temperature of 1000 to 1100° C., the growth pressure of 50 to 200 Torr, namely, about 6.7 kPa to 26.7 kPa, and a growth rate of 0.2 nm/sec., the electron supplying layer 5 may be grown on the surface 4a of the channel layer 4 by a thickness of 20 nm. The growth temperature of the electron supplying layer 5 may be set lower than that of the channel layer 4, which is 1000 to 1100° C. in the present embodiment. The growth conditions for the electron supplying layer 5 are kept constant during the grown thereof, that is, the electron supplying layer 5 becomes a homogeneous single layer. Also, the source gases inevitably contain oxygen, which is to be contained within the grown electron supplying layer 5. The electron supplying layer 5 thus grown makes a two-dimensional electrode gas (2 DEG) in the channel layer 4 next to the interface between the electron supplying layer 5 and the channel layer 4, and this 2 DEG becomes the channel region 11.

Describing the fourth step above further specifically, assuming a parameter F1 to be a total flow rate of the gas source for the group III material, that is, the Al source and the Ga source, while, another parameter F2 to be a flow rate of the gas source for the group V material, that is, the N source, the fourth step may set a ratio of the latter parameter F2 to the former parameter F1 (F2/F1) to be 5000 to 20000 in the present embodiment. The ratio greater than 5000 results in the electron supplying layer 5 with the oxygen concentration higher than the carbon concentration. Also, the ratio less than 20000 may result in crystal quality of the electron supplying layer 5 by suppressing the reaction of the Al source with the N source before reaching the surface 4a of the channel layer 4.

Another condition that the growth rate of the electron supplying layer 5 is set slower than 0.2 nm/sec may bring the result same with those above described. That is the condition of the growth rate slower than 0.2 nm/sec may raise the oxygen concentration higher than the carbon concentration in the electron supplying layer 5. That is, the fourth step may form the electron supplying layer 5 with the oxygen concentration higher than the carbon concentration by performing at least one of the conditions of the ratio (F2/F1) of the flow rate for the group V material against flow rate of the group III material between 5000 and 20000, and the growth rate slower than 0.2 nm/sec. Specifically, the flow rate of the N source is set to be 0.5 mol/min, and the total flow rate of the Al source and the Ga source is set to be 50 μmol/min, which results in the ratio of the flow rate (F2/F1) of 10,000. When the ratio of the flow rate (F2/F1) is set in the range of 5000 to 20000, the carbon atoms flowing into the growth chamber may be effectively suppressed, which results hi the electron supplying layer 5 with the oxygen concentration higher than the carbon concentration. When AlGaN layer is grown by the OMVPE technique, oxygen, carbon, and/or silicon are incorporated within the grown layer as impurities from the organic metal of the group III sources. Oxygen is incorporated within the grown layer from the Al source; however, carbon may be controlled, or reduced depending on the growth conditions described above.

The fifth step of the process further grows the cap layer 6 of GaN on the surface 5a of the electron supplying layer 5. As supplying the N source and the Ga source under the conditions of the growth temperature of 1000° C. and the growth pressure of 133 kPa, the cap layer 6 of GaN may be grown on the electron supplying layer 5 by a thickness of 5 nm as shown in FIG. 3B.

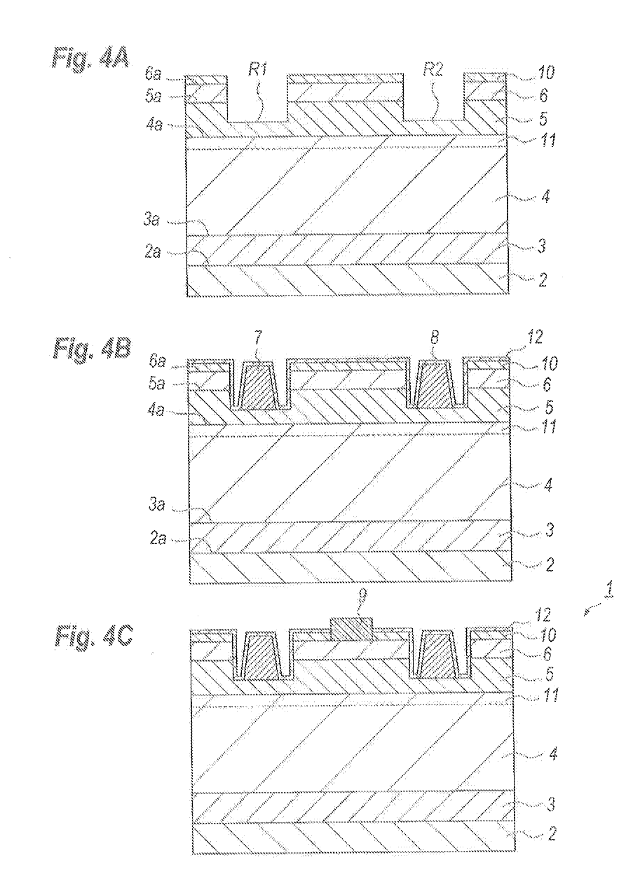

The sixth step of the process forms the passivation layer 10 on the surface 6a of the cap layer 6, and forms openings in regions where the source and drain electrodes are to be formed. Then, the cap layer 6 and the electron supplying layer 5 in the regions are partially removed to form the recesses, R1 and R2, as shown in FIG. 4A. That is, the passivation layer 10 may be an etching mask for forming the recesses, R1 and R2.

The seventh step of the process forms the source and drain electrodes, 7 and 8, in the respective recesses, R1 and R2. The source and drain electrodes, 7 and 8, may be a stack of titanium (Ti) and aluminum (Al) deposited by, for instance, the vacuum evaporation of those metals. The source and drain electrodes, 7 and 8, are covered with the insulating film 12 after the formation, thereof as shown in FIG. 4B.

The ninth step of the process forms the gate electrode 9 on the cap layer 6 as shown in FIG. 4C. Specifically, coating the insulating film 12 by a photoresist with an opening in a region where the gate electrode 9 is to be formed, and then, etching the exposed insulating film 12 and the passivation layer 10 sequentially to expose the cap layer 6, the gate electrode 9 is formed by, for instance, the vacuum evaporation of nickel (Ni) and gold (Au). Thus, the semiconductor device (electron device) according to the embodiment is completed.

Next, advantages of the semiconductor device and the process to form the semiconductor device will be described. A transistor 1, which is an embodiment of the present application, is a type of the HEMT that provides the 2 DEG induced in a region of the channel layer 4 continuous to the interface against the electron supplying layer 5. The electrons in the 2 DEG are possibly captured by electron traps formed in the channel layer 4 and also in the electron supplying layer 5, which results in the reduction of the carrier concentration of the 2 DEG and the current collapsing occurring during the pinch-off of the transistor 1. Defects and/or acceptors induced in the semiconductor layers may operate as the electron trap. Because carbon atoms contained in the electron supplying layer 5 behave as the acceptor, the higher carbon concentration causes the larger current collapsing.

In the transistor 1 formed by the process according to an embodiment of the present application, the electron supplying layer 5 provided on the channel layer 4 has the oxygen concentration higher than the carbon concentration. Because the oxygen atoms behave as donors in the electron supplying layer 5, the higher oxygen concentration equivalently reduces the effect of the acceptor. Thus, the electron supplying layer 5 of the embodiment may effectively reduce the electron traps for the 2 DEG and suppress the current collapsing of the transistor 1.

The electron supplying layer 5 of the present embodiment has the uniform aluminum distribution, which may enhance the quality of the electron supplying layer 5 and reduce the current collapsing of the transistor 1. The uniform distribution of aluminum atoms may be obtained by the process to keep the growth conditions for the electron supplying layer 5 constantly, which also means that the electron supplying layer 5 is formed in the mono-layer.

The electron supplying layer 5 has the carbon concentration less than 1×10¹⁸/cm³ in an average thereof, which is considerably less than the oxygen concentration in an average of the electron supplying layer 5. That is, the electron supplying layer 5 of the present embodiment has the oxygen concentration higher than the carbon concentration within the whole electron supplying layer 5. Thus, the configuration of the electron supplying layer 5 according to the present embodiment may effectively reduce the current collapsing.

The present invention is not restricted to those of the transistor 1 and the process to form the transistor 1. For instance, the buffer layer 3 is not always necessary for the subsequent thermal treatment performed in a temperature higher than the growth temperature. Also, the growth conditions for the buffer layer 3 are not restricted to those described above. The electron supplying layer 5 may be not always covered, with the cap layer 6.

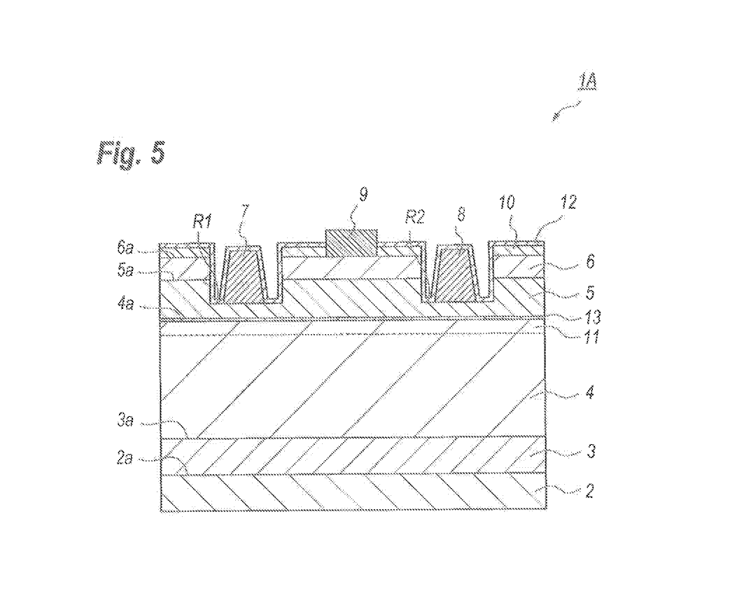

FIG. 5 shows a cross section of a transistor 1A modified from those of the first embodiment shown in FIG. 1. The transistor 1A provides, between the channel layer 4 and the electron supplying layer 5, a spacer layer 13 with a thickness of several nano-meters and made of semiconductor material including AlₓGa₁₋ₓN, or insulating material. The subscript “x” means the composition of aluminum (Al), and preferably 0.1 to 0.3 for a lower limit thereof, which is substantially the same with that in the electron supplying layer 5. The upper limit of the subscript “x” 1.0. That is, the Al composition in the spacer layer 13 is preferably 0.1 to 1.0. The spacer layer 13 spatially isolates the 2 DEG in the channel layer 11 from the dopants contained in the electron, supplying layer 5, which effectively reduces the ion-scattering of the electrons in the channel layer 4 due to the ionized dopant in the electron supplying layer 5, that is, the degradation of the electron mobility in the channel layer 11. Thus, the localized current collapsing possibly occurring in the transistor 1A may he suppressed.

Next, some practical electron device according to the present invention will be described in detail; but the present invention is not restricted to those examples.

First Example

An AlN layer with a thickness of 50 nm was first grown on a SiC substrate as the boiler layer by the OMVPE technique under the conditions of, the TMA gas and the ammonia gas as the source gases, the growth temperature of 1100° C., and the growth pressure of 103 Torr (about 13.7 kPa). A GaN layer with a thickness of 1000 nm was next grown on the AlN layer as the channel layer also by the OMVPE technique under the conditions of, the TMG gas and the ammonia gas as the source gasses, the growth temperature of 1100° C., and the growth pressure of 102 Torr (about 13.6 kPa). An AlGaN layer with a thickness of 20 nm was thirdly grown on the GaN layer as the electron supply mg layer also by the OMVPE technique under the conditions of, the TMA gas, the TMG gas, and the ammonia gas as the source gases, the growth temperature of 1000° C., and the growth pressure of 101 Torr (13.4 kPa). The growth rate of the AlGaN layer was 0.2 nm/sec. The flow rate of the ammonia gas was 0.5 mol/min, while, those of the TMA gas and the TMG gas were collectively 45 μmol/min. That is, the ratio of the flow rate of the ammonia gas against those of the group III materials was set to be 10000.

First Comparable Example

An example comparable to the first example described above was prepared by the procedures blow. That is, the AlN buffer layer and the GaN channel layer were grown on the SiC substrate by the conditions same with those of the first example, but the AlGaN layer on the GaN layer was grown by the conditions of, the growth rate of 0.28 nm/sec, the flow rate of the ammonia gas of 0.5 mol/min, and the flow rate of the group III materials of collectively 100 μmol/min.

Comparison of AlGaN Layer by SIMS

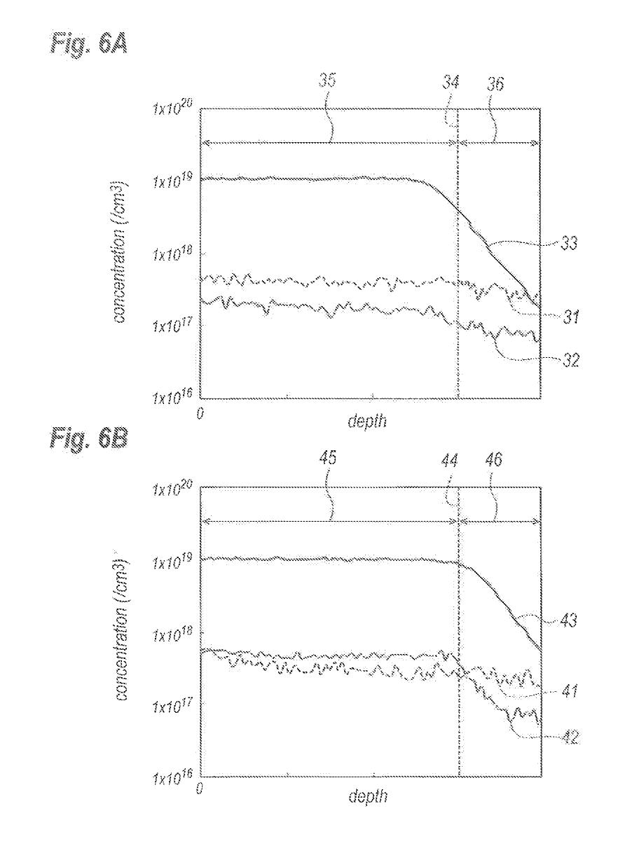

Two specimens of the first example and the first comparable example were compared by the SIMS. The SIMS of the present comparison used cesium ions (Cs⁺) for the primary ions and set the acceleration voltage thereof to be 1 kV. The primary ions were irradiated in a 135 μm square of the two specimens above to detect the depth profile of the oxygen atoms, the carbon atoms, and the aluminum atoms. FIG. 6A shows the results for the first example, while, FIG. 6B shows those for the first comparable example. The horizontal axes of two FIGS. correspond to the depth, and the vertical axes thereof denote the concentrations of respective atoms. Behaviors 31 and 41 show the depth profile of the oxygen atoms, behaviors 32 and 42 correspond to those of the carbon atoms, and behaviors 33 and 43 correspond to those of the aluminum atoms. Dotted lines, 34 and 44, show the interfaces between the AlGaN layers and the GaN layers in respective specimens, that is, respective regions 36 and 46 in right-hand sides of the dotted lines, 34 and 44, are GaN layers, while, regions 35 and 45, in left-hand sides of the dotted lines, 34 and 44, correspond to the AlGaN layer.

In FIG. 6A, the behavior 31 was higher in the whole AlGaN region 35 than the behavior 32, which means that the oxygen concentration is higher that the carbon concentration in the whole region 35, and the average concentration of the oxygen atoms is also higher than the average concentration of the carbon atoms in the region 35. On the other hand, referring to FIG. 6B, the behavior 41 was smaller than the behavior 42 in the region 45, winch means that the oxygen concentration was less than the carbon concentration in the region 45. This result inverse to those shown in FIG. 6A was considered to be due to the ratio of the flow rate of the ammonia gas against the collective rate of the group III materials.

Evaluation of Current Collapsing

One specimen of a transistor was prepared to form a cap layer with a thickness of 5 nm on a portion of the AlGaN layer of the first example described above. Also, the source electrode and foe drain electrode, each comprised on a metal stack of titanium (Ti) and Aluminum (Al), were deposited, on the AlGaN layer, while the gate electrode comprised of another metal stack of nickel (Ni) and gold (Au) was deposited on the cap layer. Another specimen of a transistor was also prepared from the first comparable example by the procedures same with those described above. The evaluation of the current collapsing was carried out as the following steps.

That is, two transistors were evaluated in the drain current against the drain bias characteristics (Vd-Id characteristic). Specifically, the drain current Id was first evaluated as increasing the drain bias Yd from 0 to 10 V under the constant gate voltage Vg of 2V. Next, two transistors of the first example and the first comparable example was stressed by setting the gate bias of −7V and the drain bias of 30V. Finally, the drain current Id was evaluated again as varying the drain bias from 0 to 10V under the constant gate bias of 2V. Two Vd-Id characteristics, namely, before and after the stress, were compared in respective transistors.

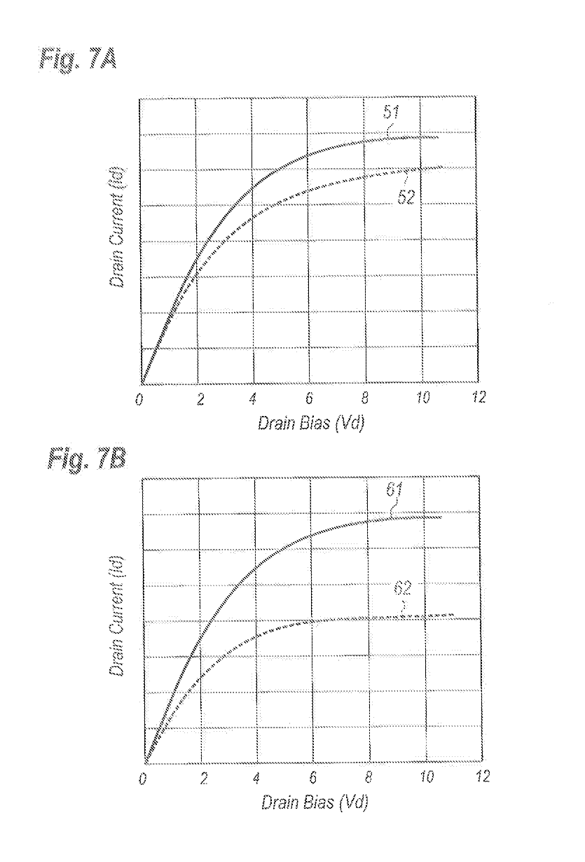

FIG. 7 A shows the Vd-Id characteristics for the first example, and FIG. 7B shows those for the first comparable example. In respective figures, solid lines, 51 and 61, correspond to the Vd-Id characteristics before the stress, while, the broken lines, 52 and 62, show the Vd-Id characteristics after the stress. As shown in figures, a difference of two behaviors, 51 and 52, is smaller compared with a difference of two behaviors, 61 and 62, in FIG. 6B. Specifically, at drain bias of 5V, the first example shows the drain current after the stress to be 80% of that before the stress. On the other hand, the first comparable example shows the drain current after the stress to be only 60% of that before the stress. Thus, the first example providing the AlGaN electron supplying layer of the present invention may effectively reduce the current collapsing. This reduction of the current collapsing may be due to the increase of the oxygen atoms, or the decrease of the carbon atoms in the electron supplying layer.

Second Example

A specimen was prepared by altering the ratio of the flow rate of the gas sources described above. That is, the specimen according to the second example of the present invention was formed by the ratio of the flow rate of the gas sources to be 5000. Other conditions were same with those of the first example.

Third Example

A specimen was prepared by altering the ratio of the flow rate of the gas sources to be 20000. Other conditions to prepare the third example were same with those of the first and second examples.

Fourth Example

A specimen was prepared by altering the growth rate of the AlGaN layer with the thickness of 20 nm. The growth rate of the AlGaN layer of Fourth Example is 0.1 nm/sec, which is slower than that of the first example. Other conditions to prepare the fourth example were same with that of the first second example.

Second Comparable Example

Second comparable example was prepared by altering the growth rate of the AlGaN layer with the thickness of 20 nm from 0.2 nm/sec of the first example to 0.25 nm/sec, which was slightly faster than that of the first example.

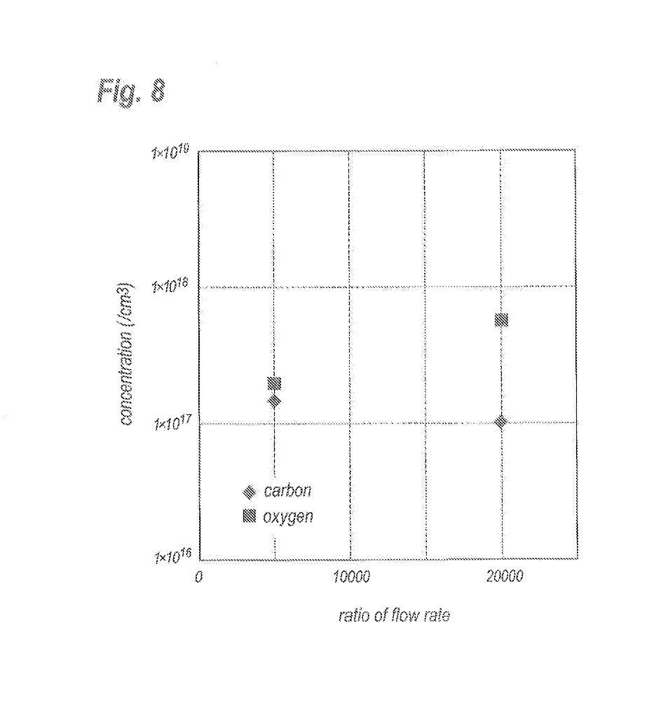

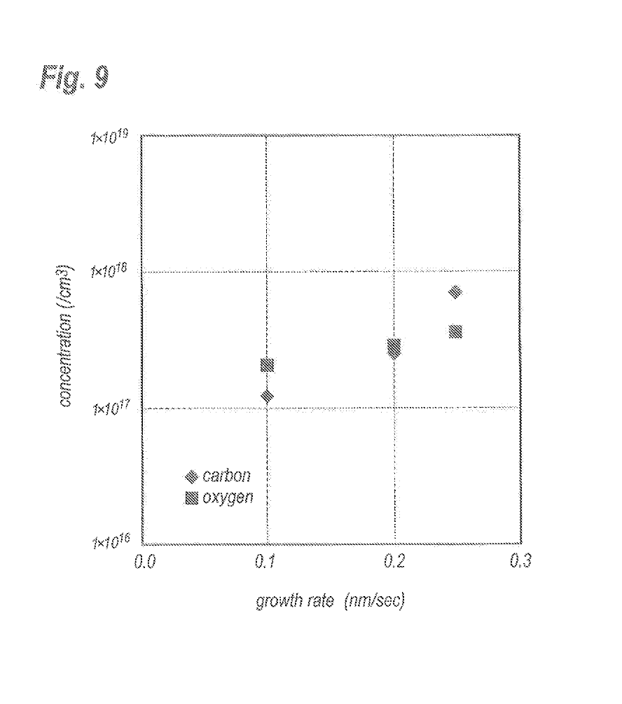

FIGS. 8 and 9 show the concentrations of the oxygen atoms and the carbon atoms in the AlGaN layer. In FIG. 8, the horizontal axis corresponds to the ratio of the gas sources and the vertical axis shows the concentrations of the oxygen atoms and the carbon atoms. FIG. 8 shows the results for the second and third examples. In FIG. 9, the horizontal axis corresponds to the growth rate of the AlGaN layer, and the vertical axis also shows the concentrations of the oxygen atoms and the carbon atoms. FIG. 9 shows the results for the first and fourth examples, and the second comparable example. In respective figures, the concentrations of the oxygen atoms and the carbon atoms are averages.

Referring to FIG. 8, the second example had the carbon concentration of 1.5×10¹⁷/cm³ and the oxygen concentration of 2.0×10¹⁷/cm³ in the AlGaN layer. Also the third example had the carbon concentration of 1.0×10¹⁷/cm³ and the oxygen concentration of 5.5×10¹⁷/cm³ in the AlGaN layer. The oxygen concentration increased but the carbon concentration decreased as the ratio of the flow rate of the gas sources increased. Thus, when the ratio of the flow rate of the gas source for the group V material against the gas source for the group III material was between 5000 and 20000, the oxygen concentration became higher than the carbon concentration in the AlGaN layer.

Referring to FIG. 9, the first example grown by the growth rate of 0.2 nm/sec had the carbon concentration of 2.4×10¹⁷/cm³ and the oxygen concentration of 2.8×10¹⁷/cm³ in the AlGaN layer. Also, the fourth example grown by the growth rate of 0.1 nm/sec had the carbon concentration of 1.2×10¹⁷/cm³ and the oxygen concentration of 2.0×10¹⁷/cm^{3.} But the second comparable example grown by the growth rate of 2.5 nm/sec reversed the relation between the carbon concentration and the oxygen concentration. That is, in the second comparable example, the carbon concentration was higher than the oxygen concentration in the AlGaN layer. Thus, the oxygen concentration in the AlGaN layer became greater as the growth rate thereof became slower. When the growth rate of the AlGaN layer is less than 0.2 nm/sec, the oxygen concentration becomes larger than the carbon concentration in the AlGaN layer.

While particular embodiments of the present invention have been described herein for purposes of illustration, many modifications and changes will become apparent to those skilled in the art. Accordingly, the appended claims are intended to encompass all such modifications and changes as fall within the true spirit and scope of this invention.

What is claimed is:

1. A semiconductor device, comprising:
a channel layer including a first nitride semiconductor;
an electron supplying layer provided on the channel layer, the electron supplying layer including a second nitride semiconductor containing aluminum (Al); and
a gate electrode, a source electrode and a drain electrode each provided on the electron supplying layer,
wherein the second nitride semiconductor has an oxygen concentration greater than a carbon concentration.

2. The semiconductor device of claim 1,
wherein the first nitride semiconductor includes a GaN, and the second nitride semiconductor includes an AlGaN having an uniform aluminum concentration.

3. The semiconductor device of claim 1,
wherein the second, nitride semiconductor has the carbon concentration less than 1×10¹⁸/cm³ in an average thereof, and the oxygen concentration less than 1×10¹⁸/cm³ in an average thereof.

4. The semiconductor device of claim 1,
wherein the second nitride semiconductor in a whole thereof has the oxygen concentration greater than the carbon concentration.

5. The semiconductor device of claim 1,
further comprising a spacer layer between the channel layer and the electron supplying layer, the spacer layer including AlₓGa₁₋ₓN having the composition x of aluminum with a lower limit substantially equal to a lower limit of aluminum composition in the second nitride semiconductor but with a higher limit of unity.

6. The semiconductor device of claim 1,
further comprising recesses in the electron supplying layer, the source electrode and the drain electrode being provided within the respective recesses.

7. The semiconductor device of claim 1,
further comprising a cap layer on the electron supplying layer,
wherein the gate electrode is provided on the cap layer.

8. The semiconductor device of claim 1,
wherein the electron supplying layer has a thickness of 20 nm.

9. A method to produce a semiconductor device, comprising steps of:
growing a first nitride semiconductor layer on a semiconductor substrate;
growing a second nitride semiconductor layer on the first nitride semiconductor layer, the second nitride semiconductor layer containing aluminum as a group III material and a nitrogen as a group V material on the first nitride semiconductor layer under a condition of a ratio of a flow rate of a source gas for the group V material to a flow rate of a source gas for the group HI material greater than 5000 but smaller than 20000; and
forming a gate electrode, a source electrode, and a drain electrode on the second nitride semiconductor layer.

10. The method of claim 9,
wherein the step of growing the second nitride semiconductor layer includes a step of growing the second nitride semiconductor layer by a constant growth condition.

11. The method of claim 9,
wherein the step of growing the second nitride semiconductor layer includes a step of growing the second nitride semiconductor layer under a condition of a growth rate slower than 0.2 nm/sec.

12. The method of claim 9,
wherein the step of growing the second nitride semiconductor layer includes a step of growing the second nitride semiconductor layer under a growth temperature lower than a growth temperature of the first nitride semiconductor layer.

13. The method of claim 12,
wherein the growth temperature of the second nitride semiconductor layer is 1000 to 1100° C.

14. The method of claim 9,
wherein the source gas for the group III material includes oxygen and carbon as impurities.

15. The method of claim 14,
wherein the second nitride semiconductor layer includes AlGaN, and
wherein the gas source for the group III material is tri-methyl-aluminum (TMA) and tri-methyl-gallium (IMG), and the gas source for the group V material is ammonia.

16. The method of claim 15,
wherein the flow rates of the TMA and TMG are collectively 50 μmol/min and the flow rate of the ammonia is 0.5 mol/min.

17. A method to produce a semiconductor device, comprising steps of:
growing a first nitride semiconductor layer on a semiconductor substrate;
growing a second nitride semiconductor layer containing aluminum as a group Hi material and nitrogen as a group V material on the first nitride semiconductor layer under a condition of a growth rate of the second nitride semiconductor layer slower than 0.2 nm/sec; and
forming a gate electrode, a source electrode, and a drain electrode on the second nitride semiconductor layer.

18. The method of claim 17,
wherein the step of growing the second nitride semiconductor layer Includes a step of growing the second nitride semi conductor layer by a constant growth condition.
